(19) United States
(12) Patent Application Publication
(10) Pub. No.: US 2022/0013562 A1
(43) Pub. Date: Jan. 13, 2022

(54) IMAGE SENSING DEVICE

(71) Applicant: SK hynix Inc., Icheon-si (KR)

(72) Inventors: Yun Hui YANG, Icheon-si (KR); Jung Yong CHAE, Icheon-si (KR)

(21) Appl. No.: 17/183,211

(22) Filed: Feb. 23, 2021

(30) Foreign Application Priority Data
Jul. 13, 2020 (KR) 10-2020-0085894

(51) Int. Cl. H01L 27/146

(52) U.S. Cl. CPC H01L 27/14623; H01L 27/14603

(57) ABSTRACT

An image sensing device is provided to include a semiconductor substrate having a first surface and a second surface and including different portions for a pixel region including pixel structures and a pad region, a first pad metal layer formed over the first surface of the semiconductor substrate and located in the pad region, an anti-reflection layer formed over a first portion of the first pad metal layer to contact a top surface of the first pad metal layer, and a pad passivation layer formed over the first pad metal layer and the anti-reflection layer. A second portion of the first pad metal layer is provided as a pad open region formed to expose the top surface of the first pad metal layer and an interface between the first pad metal layer and the anti-reflection layer are structured not to be exposed to an outside.

### CROSS-REFERENCE TO RELATED APPLICATION

This patent document claims the priority and benefits of Korean patent application No. 10-2020-0085894, filed on Jul. 13, 2020, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices for capturing at least one image using semiconductor characteristics that react to light. With the recent development of automotive, medical, computer and communication industries, the demand for highly integrated, higher-performance image sensors is rapidly increasing in various fields, for example, digital cameras, camcorders, personal communication systems (PCSs), game consoles, surveillance cameras, medical micro-cameras, robots, etc.

Image sensing devices may be broadly classified into CCD (Charge Coupled Device) image sensing devices and CMOS (Complementary Metal Oxide Semiconductor) image sensing devices. Recently, since an analog control circuit and a digital control circuit can be directly implemented as a single integrated circuit (IC), CMOS image sensing devices have been widely used.

### SUMMARY

Various embodiments of the disclosed technology relate to an image sensing device provided with a pad having higher reliability.

In one aspect, an image sensing device is provided to include a semiconductor substrate including a pixel region and a pad region, and structured to include a first surface and a second surface facing each other or opposite to each other; a first pad metal layer formed over the first surface of the semiconductor substrate in the pad region; an anti-reflection layer formed to contact a top surface of the first pad metal layer, and formed in some regions of the top surface of the first pad metal layer; a pad passivation layer formed over the first pad metal layer and the anti-reflection layer; and a pad open region formed to expose the top surface of the first pad metal layer, and structured to prevent an interface between the first pad metal layer and the anti-reflection layer from being exposed outside.

In another aspect, an image sensing device is provided to include a semiconductor substrate having a first surface and a second surface opposite to the first surface and including different portions for a pixel region including pixel structure and a pad region used to provide external electrical connections, a first pad metal layer formed over the first surface of the semiconductor substrate and located in the pad region, an anti-reflection layer formed over a first portion of the first pad metal layer to contact a top surface of the first pad metal layer, and a pad passivation layer formed over the first pad metal layer and the anti-reflection layer. A second portion of the first pad metal layer is provided as a pad open region formed to expose the top surface of the first pad metal layer and an interface between the first pad metal layer and the anti-reflection layer is structured not to be exposed to an outside.

In another aspect, an image sensing device is provided to include a pixel region including a plurality of unit pixels, each unit pixel structured to provide a pixel signal by converting incident light into an electrical signal, and a pad region located on a side of the pixel region and structured to include a plurality of pads to be electrically coupled to an external circuit. The pad region may include a first region in which a first pad metal layer is exposed outside by a pad open region, a second region in which an anti-reflection layer contacting a top surface of the first pad metal layer and a pad passivation layer contacting top and side surfaces of the anti-reflection layer are formed, and a third region disposed between the first region and the second region and formed in a manner that the pad passivation layer is extended to be formed over the top surface of the first pad metal layer.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example layout of an image sensing device based on some implementations of the disclosed technology.

FIG. 2 is a cross-sectional view illustrating an example of the image sensing device taken along the line A-A′ shown in FIG. 1 based on some implementations of the disclosed technology.

FIG. 3 is an enlarged cross-sectional view illustrating an example of a region denoted by a dotted circle shown in FIG. 2 based on some implementations of the disclosed technology.

FIGS. 4 to 10 are cross-sectional views illustrating an example of processes for forming the structure shown in FIG. 2 based on some implementations of the disclosed technology.

### DETAILED DESCRIPTION

This patent document provides implementations and examples of an image sensing device. Some implementations of the disclosed technology suggest designs of an image sensing device provided with a pad having higher reliability. The disclosed technology provides various implementations of an image sensing device which can improve reliability of a pad by increasing the degree of passivation on heterogeneous metal layers used in the pad.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

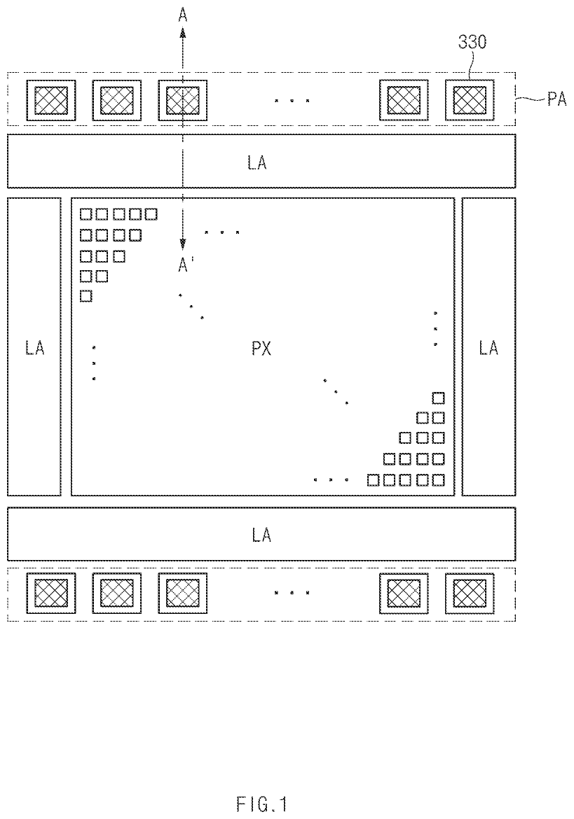

FIG. 1 is a schematic diagram illustrating an example layout of an image sensing device based on some implementations of the disclosed technology.

Referring to FIG. 1, the image sensing device may include a pixel region PX, a logic region (or logic area) LA, and a pad region (or pad area) PA.

The pixel region PX may be located at the center of the image sensing device, and may include a plurality of unit pixels. The plurality of unit pixels may convert incident light into electrical signals corresponding to the incident light, and may thus generate a pixel signal using the electrical signals. The unit pixels may include image pixels capable of selectively sensing red light (R), green light (G), or blue light (B). The unit pixels may be arranged in a two-dimensional (2D) matrix form, and may be arranged in, for example, a Bayer pattern. The unit pixels may include photoelectric conversion elements, color filters, microlenses, and pixel transistors. In some implementations, the photoelectric conversion elements may be formed in a semiconductor substrate, the color filters and the microlenses may be formed over a first surface of the semiconductor substrate, and the pixel transistors may be formed over a second surface arranged to face against the first surface of the semiconductor substrate.

The logic region LA may be located outside the pixel region PX to make it easier to receive the electrical signals converted from the light incident on the pixel region PX. For example, the logic region LA may be located outside the pixel region PX. The logic region LA may include a plurality of logic circuits to operate pixel transistors of the pixel region PX and process pixel signals generated by the pixel region PX. This logic region LA may include various logic circuits, for example, a correlated double sampler (CDS), an analog-to-digital converter (ADC), a ramp signal generator, and an image processor.

The pad region PA may be located near the logic region LA so that the logic region LA can communicate with external devices via the pad region PA. For example, the pad region PA may be located outside the logic region LA, and may include a plurality of pads 330 to electrically couple the logic circuits of the logic region LA to an external circuit. Each pad 330 may include a stacked structure of different kinds of metal layers that are in contact with each other. For example, each pad 330 may be formed as a stacked structure of an aluminum (Al) film, a tungsten (W) film, and an anti-reflection layer (e.g., titanium nitride (TiN), tantalum nitride (TaN), tungsten nitride (WN), etc.). A pad 330 may include an open region around a center of the pad 330 and an edge region surrounding the open region. In some implementations, the center portion of the pad 330 in which a pad open region is formed may be formed in a structure in which the aluminum (Al) film is formed over the tungsten (W) film. The edge region of the pad 330 surrounding the pad open region may be formed in a structure in which the tungsten (W) film, the aluminum (Al) film, and the anti-reflection layer are sequentially stacked in a vertical direction. In the pad 330, only the pad open region may be exposed to the outside, and the remaining regions other than the pad open region may be covered by a pad passivation layer. In this case, an interface between metal layers of the pad 330 may be structured not to be exposed to the outside by the pad open region. In some implementations, when the metal layer is formed as an anti-reflection layer over the aluminum (Al) film of the pad 330, an interface between the aluminum (Al) film and the anti-reflection layer is not exposed to the outside, such that undesired effects, e.g., the galvanic corrosion, can be prevented from occurring in the interface between the aluminum (Al) film and the anti-reflection layer. The structure of the pad 330 will hereinafter be described with reference to the attached drawings.

Although FIG. 1 illustrates an example implementation in which the pad region PA is located only at two sides of the pixel region PX for convenience of description, it should be noted that the pad region PA can also be arranged to surround the pixel region PX.

In addition, although FIG. 1 illustrates an example implementation in which the logic region LA is formed between the pixel region PX and the pad region PA for convenience of description, other implementations are also possible. For example, when the image sensing device is formed in a three-dimensional (3D) stack structure in which the semiconductor substrates are stacked, the logic region LA may also be disposed below the pixel region PX.

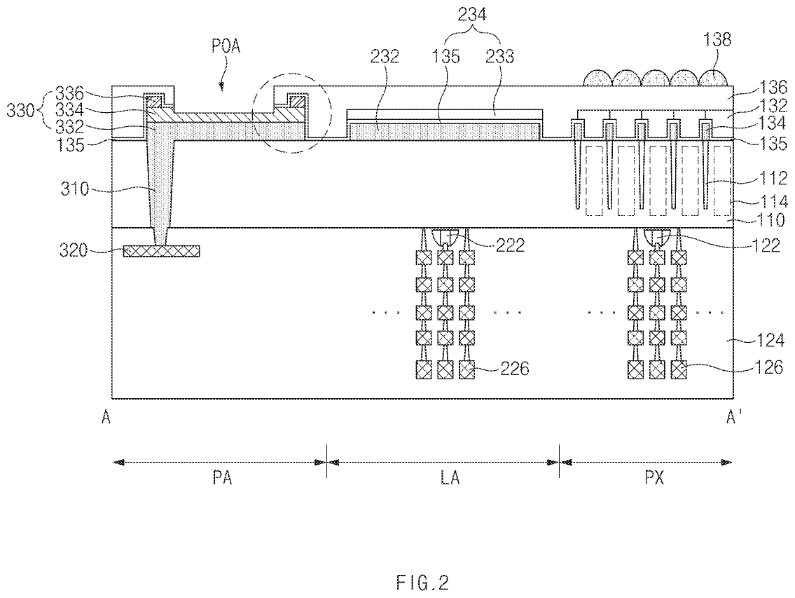

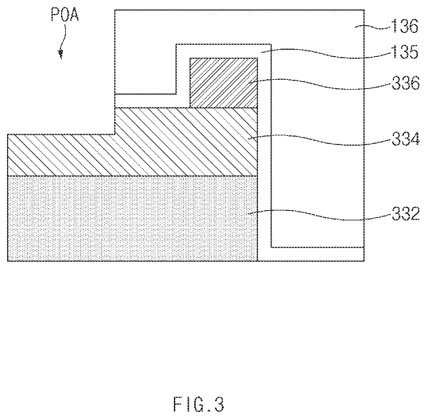

FIG. 2 is a cross-sectional view illustrating an example of the image sensing device taken along the line A-A′ shown in FIG. 1 based on some implementations of the disclosed technology. FIG. 3 is an enlarged cross-sectional view illustrating an example of a region denoted by a dotted circle shown in FIG. 2 based on some implementations of the disclosed technology.

Referring to FIGS. 2 and 3, the semiconductor substrate 110 may include a pixel region PX, a logic region LA, and a pad region PA.

The pixel region PX may include a plurality of unit pixels, each of which generates a pixel signal by converting incident light into an electrical signal. In the semiconductor substrate 110 of the pixel region PX, a plurality of photoelectric conversion elements (e.g., photodiodes) 114 structured to perform photoelectric conversion of incident light, and a device isolation layer 112 structured to isolate contiguous (or adjacent) photoelectric conversion elements 114 from each other may be formed. The device isolation layer 112 may include a trench-shaped device isolation structure in which insulation materials are buried in a trench formed by etching the semiconductor substrate 110. For example, the device isolation layer 112 may include a deep trench isolation (DTI) structure.

In the pixel region PX, a plurality of color filters 132, a pixel grid 134, and a plurality of microlenses 138 may be formed over a first surface (e.g., a light incident surface) of the semiconductor substrate 110. The color filters 132 may perform filtering of incident light, and may thus selectively transmit visible light (e.g., red light, green light, or blue light) at a certain wavelength while blocking light at other wavelengths. The pixel grid 134 may be disposed between the color filters 132 to prevent crosstalk between the adjacent color filters 132. The microlenses 138 may focus incident light to the photoelectric conversion elements 114.

The pixel grid 134 may be formed at a boundary region between the color filters 132, and may define a plurality of windows structured to vertically overlap with the photoelectric conversion elements 114. The color filters 132 may be formed in the windows, respectively. The pixel grid 134 may include a metal layer. For example, the pixel grid 134 may include a lower metal layer and an upper metal layer. In some implementations, the lower metal layer may include a barrier metal material, for example, titanium (Ti), titanium nitride (TiN), tantalum (Ta), tantalum nitride (TaN), or tungsten nitride (WN). The upper metal layer may include tungsten (W). An insulation layer 135 structured to prevent collapse of the metal layer in a thermal annealing process may be formed over the pixel grid 134. The insulation layer 135 may be formed at top and side surfaces of the pixel grid 134, and may extend to a region between the semiconductor substrate 110 and the color filters 132, such that the insulation layer 135 may also operate as an anti-reflection layer. In addition, the insulation layer 135 may be formed to extend to the logic region LA and the pad region PA. The insulation layer 135 may include a nitride film or an oxide film. The nitride film may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number). The oxide film may include an Undoped Silicate Glass (USG) film.

The color filters 132 may include a plurality of red color filters, a plurality of green color filters, and a plurality of blue color filters. Each red color filter may transmit only light in red wavelength regions of visible light upon receiving incident light through the microlenses 138. Each green color filter may transmit only light in green wavelength regions of visible light upon receiving incident light through the microlenses 138. Each blue color filter may transmit only light in blue wavelength regions of visible light upon receiving incident light through the microlenses. The red color filter from among the color filters 132 may include a polymer organic material including a red pigment. The green color filter from among the color filters 132 may include a polymer organic material including a green pigment. The blue color filter from among the color filters 132 may include a polymer organic material including a blue pigment. For example, the red color filter from among the color filters 132 may include a resist film including a red pigment, the green color filter from among the color filters 132 may include a resist film including a green pigment, and the blue color filter from among the color filters 132 may include a resist film including a blue pigment.

An over-coating layer 136 may be formed between the microlenses 138 and the color filters 132. In the pixel region PX, the over-coating layer 136 may operate as a planarization layer to compensate for (or remove) a step difference caused by the color filters 132. The over-coating layer 136 may be formed to extend to the logic region LA and the pad region PA. The over-coating layer 136 may have the same materials as those of the microlenses. For example, the over-coating layer 136 may include a polymer organic material.

In the pixel region PX, pixel transistors 122, an interlayer insulation layer 124, and metal lines 126 may be formed over the second surface that is facing or opposite to the first surface of the semiconductor substrate 110. The pixel transistors 122 may include transistors to read out electrical signals generated by the photoelectric conversion elements 114.

The logic region LA may be located outside the pixel region PX. In the logic region LA, a shield structure configured to prevent incident light from being incident upon the semiconductor substrate 110 may be formed over the first surface of the semiconductor substrate 110.

The shield structure may include a light shielding layer 232 and an anti-reflection layer 234. The light shielding layer 232 may include a metal layer. The light shielding layer 232 of the logic region LA and the pixel grid 134 of the pixel region PX may be formed at the same time. For example, the light shielding layer 232 may have the same materials as those of the pixel grid 134, and may be patterned simultaneously with patterning of the pixel grid 134. The anti-reflection layer 234 may enable light to be incident upon the light shielding layer 232, and may prevent the incident light from being reflected from the light shielding layer 232. The anti-reflection layer 234 may include insulation layers 135 and 233 formed over the light shielding layer 232. The insulation layer 135 may be formed over top and side surfaces of the light shielding layer 232. The insulation layer 135 of the logic region LA may be formed simultaneously with formation of the insulation layer 135 of the pixel region PX. For example, when the insulation layer 135 is formed over the pixel grid 134, the insulation layer 135 may also be formed over the light shielding layer 232 of the logic region LA. When the insulation layer 135 is formed over the pixel grid 134, the insulation layer 135 may also be formed at top and side surfaces of the light shielding layer 232 of the logic region LA. The insulation layer 233 may be formed over the insulation layer 135 to vertically overlap with the entire region of the light shielding layer 232. The insulation layer 233 may be formed together with the color filters 132 of the pixel region PX. The insulation layer 233 may include a polymer organic material including a red pigment, a green pigment, or a blue pigment. For example, the insulation layer 233 may include a resist film including a blue pigment. The over-coating layer 136 may be formed over the shield structure.

In the logic region LA, the logic transistor 222, the interlayer insulation layer 124, and metal lines 226 may be formed over the second surface of the semiconductor substrate 110. The logic transistor 222 may include a plurality of transistors structured to process signals that have been read out from the pixel region PX.

The pad region PA may be located outside the logic region LA. In the pad region PA, a through silicon via (TSV) formed to penetrate the semiconductor substrate 110 may be formed. The through silicon via (TSV) 310 may be integrated with a metal layer 332 of the pad 330 and be formed as one body. For example, the through silicon via (TSV) 310 may have the same materials as those of the metal layer 332, and may be formed together with the metal layer 332.

In the pad region PA, the pad 330 coupled to the through silicon via (TSV) 310 may be formed over the first surface of the semiconductor substrate 110. The pad 330 may include a stacked structure of different kinds of metal layers that are arranged to be in contact with each other. For example, the pad 330 may include a lower pad metal layer 332 formed over the semiconductor substrate 110 to be coupled to the through silicon via (TSV) 310, an upper pad metal layer 334 formed over the lower pad metal layer 332, and an anti-reflection layer 336 formed over the upper pad metal layer 334.

The lower pad metal layer 332 may be formed simultaneously with formation of the pixel grid 134 of the pixel region PX and the light shielding layer 232 of the logic region LA. For example, the pad metal layer 332 may have the same materials as that in the pixel grid 134 and the light shielding layer 232. The upper pad metal layer 334 may be formed over the lower pad metal layer 332 to be in contact with a top surface of the lower pad metal layer 332. The upper pad metal layer 334 may include an aluminum (Al) film, and the center portion of a top surface of the upper pad metal layer 334 may be exposed to the outside by a pad open region POA. The anti-reflection layer 336 may be formed in an edge region of the upper pad metal layer 334 in a band shape surrounding the center portion of the pad metal layer 334. In some implementations, the anti-reflection layer 336 may be formed over the remaining portion that is not the center portion of the upper pad metal layer 334, which allows the remaining portion of the upper pad metal layer 334 not to be exposed to the outside. The anti-reflection layer 336 may include titanium nitride (TiN), tantalum nitride (TaN), or tungsten nitride (WN). The anti-reflection layer 336 may also serve as a barrier film.

The insulation layer 135 and the over-coating layer 136 may be formed at top and side surfaces of the pad 330, which correspond to the remaining parts other than the pad open region POA. The insulation layer 135 and the over-coating layer 136 may be used as a pad passivation layer structured to protect the pad 330. The pad open region POA may correspond to the region in which the insulation layer 135 and the over-coating layer 136 are not provided in the pad region PA. In some implementations, among the metal layers 332, 334, and 336 of the pad 330 only the upper pad metal layer 334 may be exposed to the outside by the pad open region POA. For example, at the top surface of the upper pad metal layer 334, a region defined by the anti-reflection layer 336 may not be exposed to the outside by the pad open region POA. Thus, only some parts of the top surface of the upper pad metal layer 334 may be exposed to the outside by the pad open region POA. In this case, the region defined by the anti-reflection layer 336 may denote a specific region that is surrounded by the anti-reflection layer 336 at the top surface of the upper pad metal layer 334.That is, the region exposed outside by the pad open region POA may be smaller in size than the region defined by the anti-reflection layer 336. With the structure, it is possible to prevent the anti-reflection layer 336 from being exposed outside by the pad open region POA.

The pad 330 may be formed in a stacked structure of different kinds of metal layers 332, 334, and 336 that are arranged to be in contact with each other. When the interface between different metal layers is exposed to the outside by the pad open region POA, there is a high possibility of galvanic corrosion that occurs in the interface between such different metal layers due to moisture or humidity. In particular, the exposed interface may be more vulnerable to galvanic corrosion when tested in a Temperature Humidity Bias (THB) test in which a voltage is applied in a high-temperature and high-humidity state.

In order to prevent galvanic corrosion, when the anti-reflection layer 336 may be formed in the edge region of the top surface of the upper pad metal layer 334, an interface between the upper pad metal layer 334 and the anti-reflection layer 336 may be formed not to be exposed by the pad open region POA. For example, as illustrated in FIG. 3, top and side surfaces of the anti-reflection layer 336 may be capped (or covered) by the insulation layer 135 and the over-coating layer 136, and the pad open region POA may be formed at the center portion of the top surface of the upper pad metal layer 334 to be spaced apart from the anti-reflection layer 336 by a predetermined distance.

In the pad region PA, a metal line 320 coupled to the through silicon via (TSV) 310 may be formed in the interlayer insulation layer 124 over the second surface of the semiconductor substrate 110. The metal line 320 may be electrically coupled to metal lines 226 of the logic region LA.

Although FIG. 2 illustrates an example implementation in which the light shielding layer 232 of the logic region LA and the lower pad metal layer 332 of the pad region PA are separated from each other for convenience of description, the light shielding layer 232 and the pad metal layer 332 may also be integrated with each other in one body as necessary.

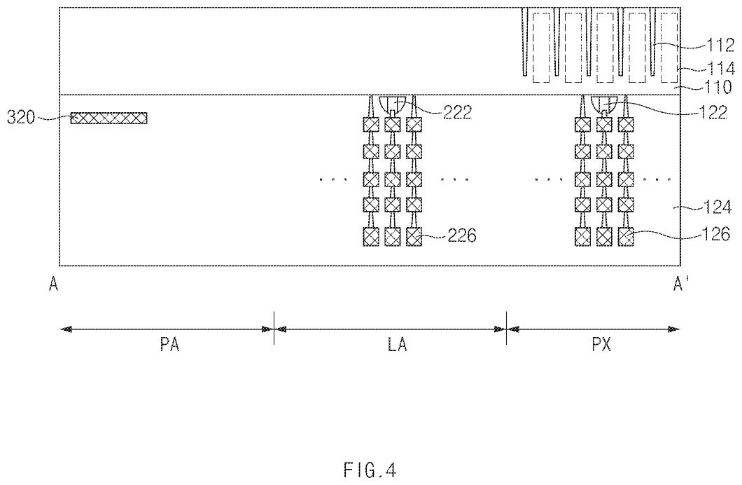

FIGS. 4 to 10 are cross-sectional views illustrating an example of processes for forming the structure shown in FIG. 2 based on some implementations of the disclosed technology.

Referring to FIG. 4, photoelectric conversion elements 114 may be formed in the semiconductor substrate 110 of the pixel region PX. Each of the photoelectric conversion elements 114 may be a photodiode including an N-type impurity region and a P-type impurity region, and may be formed by impurity ion implantation. The photodiode is only one example of the photoelectric conversion elements and can be implemented any element that can produce an electrical signal in response to received light. Other examples of the photoelectric conversion element may include a photo transistor, a photo gate, or other photosensitive circuitry capable of converting light into a pixel signal.

Subsequently, at the second surface of the semiconductor substrate 110, pixel transistors 122 structured to read out electrical signals generated by the photoelectric conversion elements 114 may be formed in the pixel region PX, and logic transistors 222 structured to process the electrical signals read out from the pixel region PX may be formed in the logic region LA.

Then, interlayer insulation layers 124 and metal lines 126 and 226 may be formed over the pixel transistors 122 and the logic transistors 222. In this case, the metal line 320 coupled to the through silicon via (TSV) 310 may be formed in the pad region PA. The metal lines 126, 226, and 320 may be electrically coupled to each other.

Thereafter, after a mask pattern (not shown) defining a device isolation region is formed over the first surface of the semiconductor substrate 110, the semiconductor substrate 110 may be etched using the mask pattern as an etch mask, such that a trench for device isolation (not shown) may be formed in the semiconductor substrate 110. Subsequently, an insulation material for device isolation may be buried in the device isolation trench, such that a device isolation layer 112 may be formed between the photoelectric conversion elements 114.

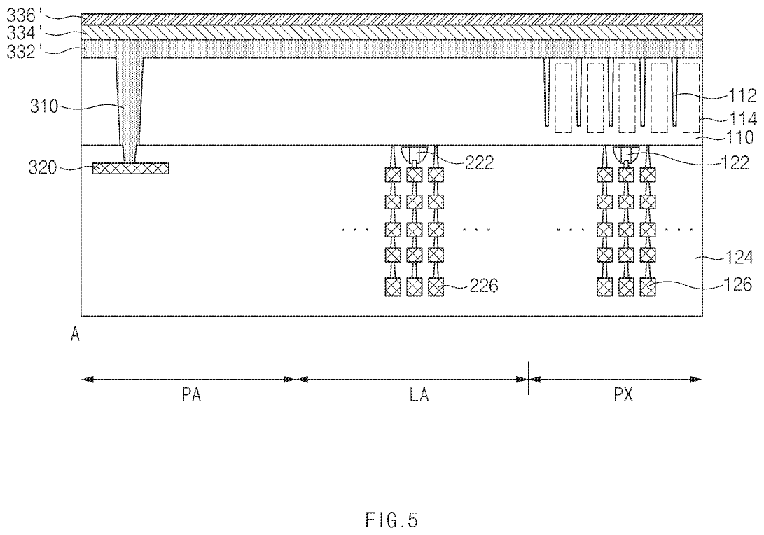

Referring to FIG. 5, the semiconductor substrate 110 corresponding to a specific region to be used for the through silicon via (TSV) 310 in the pad region PA may be etched, resulting in formation of a through silicon via (TSV) in the pad region PA. Subsequently, an insulation layer (not shown) may be formed at an inner surface of the through silicon via (TSV), and the interlayer insulation layer 124 exposed by the through silicon via (TSV) may be etched, resulting in formation of a trench (not shown) exposing the metal line 320.

A metal material may be formed over the semiconductor substrate 110 of the pad region PA, the logic region LA, and the pixel region PX in a manner that the through silicon via (TSV) and the trench can be buried with the metal material, resulting in formation of the through silicon via (TSV) 310 and a metal layer 332′. In this case, each of the through silicon via (TSV) 310 and the metal layer 332′ may include tungsten (W) or may include a stacked structure of barrier metal and tungsten (W).

Subsequently, metal layers 334′ and 336′ may be sequentially formed over the metal layer 332′. In this case, the metal layer 334′ may include aluminum (Al). The metal layer 336′ may include at least one of titanium nitride (TiN), tantalum nitride (TaN), and tungsten nitride (WN).

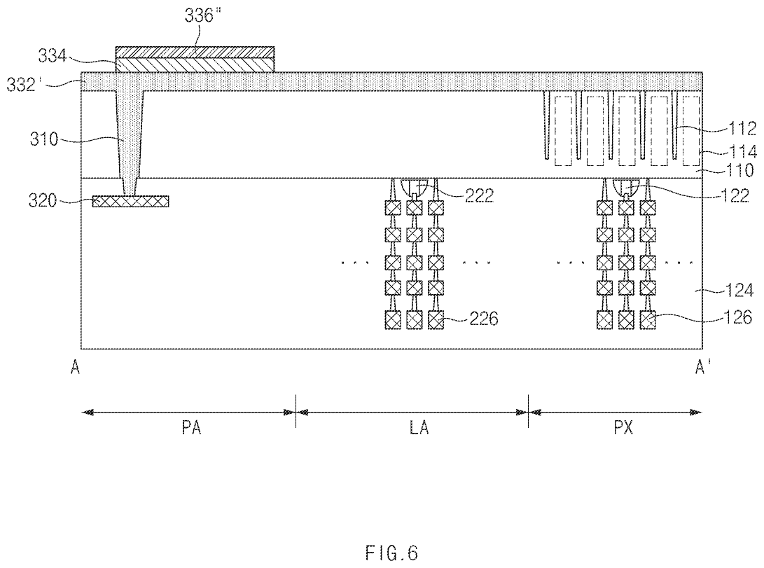

Referring to FIG. 6, a mask pattern that defines a region to be used for pad formation may be formed over the metal layer 336′, and the metal layers 334′ and 336′ may be etched using the mask pattern as an etch mask, such that an upper pad metal layer 334 and a metal layer pattern 336″ may be formed over the metal layer 332′.

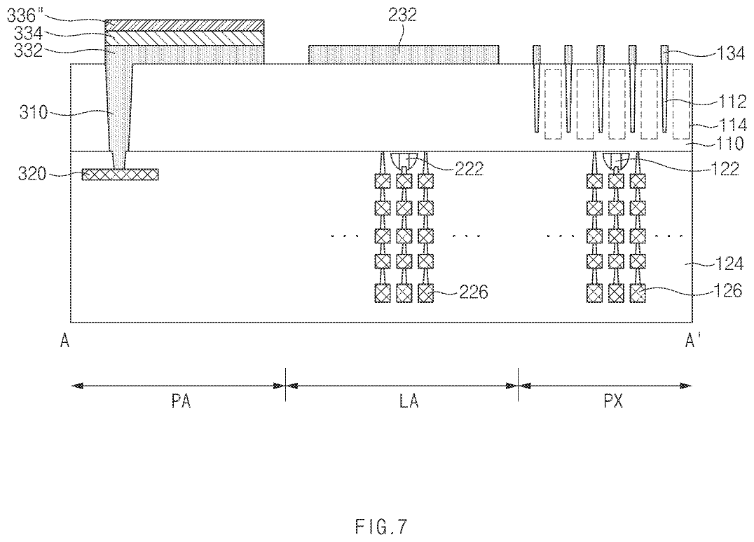

Referring to FIG. 7, the metal layer 332′ may be patterned to form the pixel grid 134 in the pixel region PX, the light shielding layer 232 may be formed in the logic region LA, and the lower pad metal layer 332 may be formed in the pad region PA.

Although the above-mentioned implementation of the disclosed technology has disclosed an example implementation in which the light shielding layer 232 of the logic region LA and the lower pad metal layer 332 of the pad region PA are separated from each other for convenience of description, the light shielding layer 232 and the lower pad metal layer 332 may be integrated with each other in one body. For example, the through silicon via (TSV) 310, the lower pad metal layer 332, and the light shielding layer 232 may also be integrated with each other in one body as needed.

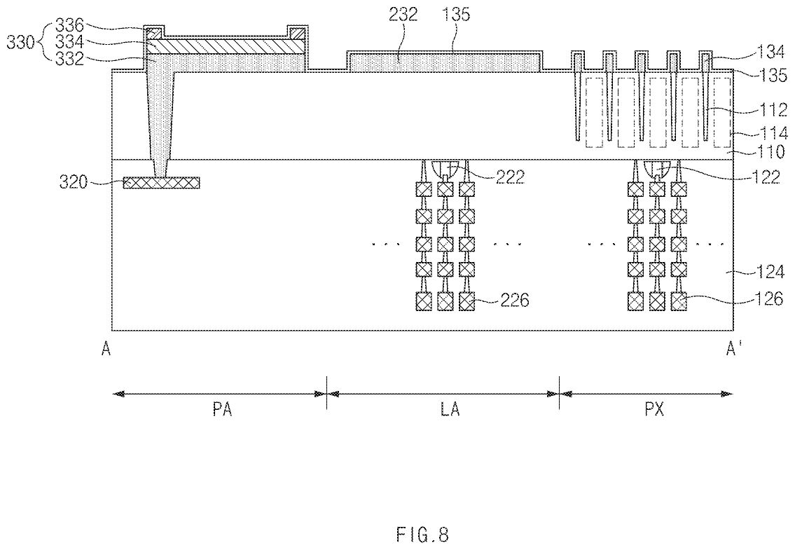

Referring to FIG. 8, the metal layer pattern 336″ may be partially removed to form the anti-reflection layer 336. For example, the center portion of the metal layer pattern 336″ may be partially removed, such that the anti-reflection layer 336 may be formed in a rectangular band shape in which the metal layer remains only in the edge region from among the top surface of the upper pad metal layer 334. In this case, the region from which the metal layer pattern 336″ is removed may be larger in width than the pad open region POA to be formed in a subsequent process.

As a result, the pad in which different kinds of metal layers are stacked may be formed in the pad region PA.

Thereafter, the insulation layer 135 may be formed in the pixel region PX, the logic region LA, and the pad region PA to cover the pixel grid 134, the light shielding layer 232, and the pad 330. The insulation layer 135 may include a nitride film or an oxide film.

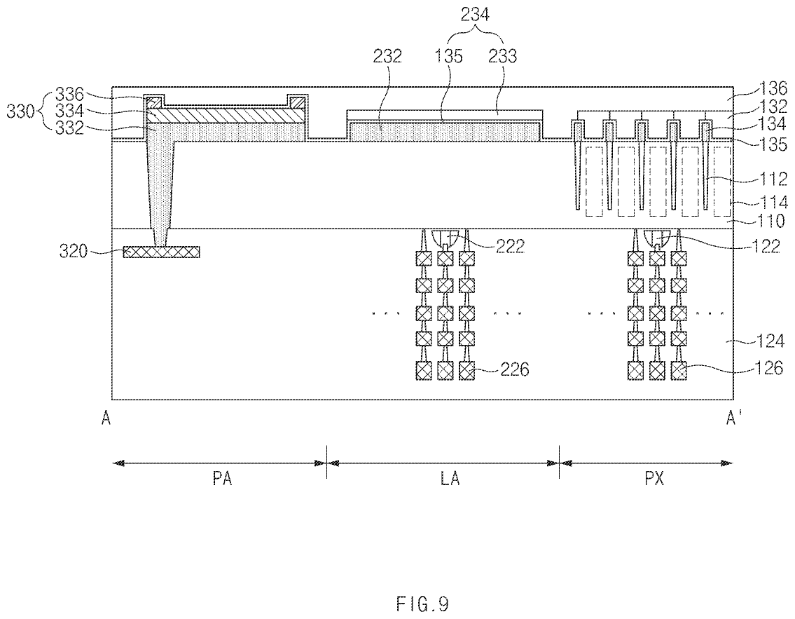

Referring to FIG. 9, the color filters 132 may be formed in regions defined by the pixel grid 134 within the pixel region PX. When the color filters 132 are formed, the insulation layer 233 serving as a portion of the anti-reflection layer 234 may be formed over the insulation layer 135 in the logic region LA. In this case, the insulation layer 233 may include a photoresist film including a blue pigment. For example, the insulation layer 233 may be formed simultaneously with formation of the blue color filter from among the color filters 132.

As a result, the shield structures 232 and 234 may be formed in the logic region LA.

Subsequently, the over-coating layer 136 may be formed in the pixel region PX, the logic region LA, and the pad region PA to cover the color filters 132, the shield structures 232 and 234, and the pad 330.

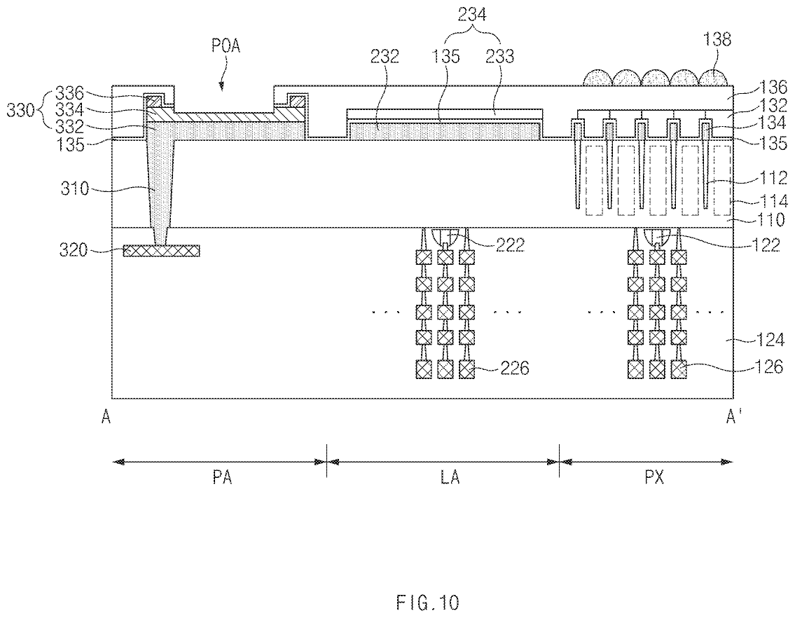

Referring to FIG. 10, microlenses 138 may be formed over the over-coating layer 136 in the pixel region PX.

Subsequently, the over-coating layer 136 and the insulation layer 135, that are located at the center of the pad 330, may be removed from the pad region PA, such that the pad open region POA by which the upper pad metal layer 334 is exposed outside can be formed in the pad region PA. In this case, the pad open region POA may be spaced apart from the anti-reflection layer 336 by a predetermined distance to prevent the interface between the upper pad metal layer 334 and the anti-reflection layer 336 from being exposed outside. For example, at the top surface of the upper pad metal layer 334, the region exposed outside by the pad open region POA may be smaller in size than the region (i.e., the region in which the anti-reflection layer 336 is not formed at the top surface of the upper pad metal layer 334) defined by the anti-reflection layer 336.

As described above, when the pad 330 based on some implementations of the disclosed technology includes a stacked structure of different kinds of metal layers, the interface between the metal layers is not exposed outside, such that occurrence of galvanic corrosion can be prevented.

As is apparent from the above description, the image sensing device based on some implementations of the disclosed technology can improve reliability of the pad by increasing the degree of passivation on heterogeneous metal layers used in the pad.

Although a number of illustrative embodiments have been described, various modifications and enhancements to the disclosed embodiments and other embodiments can be devised based on what is described and/or illustrated in this patent document.

What is claimed is:

1. An image sensing device comprising:
a semiconductor substrate having a first surface and a second surface opposite to the first surface and including different portions for a pixel region including pixel structures and a pad region used to provide external electrical connections;
a first pad metal layer formed over the first surface of the semiconductor substrate and located in the pad region;
an anti-reflection layer formed over a first portion of the first pad metal layer to contact a top surface of the first pad metal layer; and
a pad passivation layer formed over the first pad metal layer and the anti-reflection layer,
wherein a second portion of the first pad metal layer is provided as a pad open region formed to expose the top surface of the first pad metal layer and an interface between the first pad metal layer and the anti-reflection layer are structured not to be exposed to an outside.

2. The image sensing device according to claim 1, wherein:
the anti-reflection layer is formed in an edge region of the top surface of the first pad metal layer.

3. The image sensing device according to claim 2, wherein:
the anti-reflection layer is formed to surround a center portion of the top surface of the first pad metal layer.

4. The image sensing device according to claim 3, wherein the pad open region has a smaller size than a region that is over the first pad metal layer and defined by the anti-reflection layer.

5. The image sensing device according to claim 3, wherein:
the pad passivation layer is formed to cover top and side surfaces of the anti-reflection layer, and is formed to extend to some regions of the top surface of the first pad metal layer.

6. The image sensing device according to claim 1, wherein:
the first pad metal layer and the anti-reflection layer include different metal materials from each other.

7. The image sensing device according to claim 6, wherein:
the first pad metal layer includes aluminum (Al); and
the anti-reflection layer includes at least one of titanium nitride (TiN), tantalum nitride (TaN), or tungsten nitride (WN).

8. The image sensing device according to claim 1, further comprising:
a conductive line disposed over the second surface of the semiconductor substrate; and
a through silicon via (TSV) formed to penetrate the semiconductor substrate to electrically interconnect the first pad metal layer and the conductive line.

9. The image sensing device according to claim 8, further comprising:
a second pad metal layer disposed between the first pad metal layer and the through silicon via (TSV).

10. The image sensing device according to claim 9, wherein:
the second pad metal layer is integrated with the through silicon via (TSV).

11. The image sensing device according to claim 1, wherein:
the pad passivation layer is formed to extend to the pixel region.

12. An image sensing device comprising:
a pixel region including a plurality of unit pixels, each unit pixel structured to provide a pixel signal by converting incident light into an electrical signal; and
a pad region located on a side of the pixel region, and structured to include a plurality of pads to be electrically coupled to an external circuit,
wherein the pad region includes:
a first region in which a first pad metal layer is exposed to an outside by a pad open region;
a second region in which an anti-reflection layer contacting a top surface of the first pad metal layer and a pad passivation layer contacting top and side surfaces of the anti-reflection layer are formed; and
a third region disposed between the first region and the second region, and formed in a manner that the pad passivation layer is extended to be formed over the top surface of the first pad metal layer.

13. The image sensing device according to claim 12, wherein:
the second region is formed in a shape surrounding the first region.

14. The image sensing device according to claim 12, wherein:
the pad passivation layer is formed to extend to the pixel region.

15. The image sensing device according to claim 12, wherein:
the first pad metal layer and the anti-reflection layer include different metal materials from each other.

16. The image sensing device according to claim 15, wherein:
the first pad metal layer includes aluminum (Al); and
the anti-reflection layer includes at least one of titanium nitride (TiN), tantalum nitride (TaN), or tungsten nitride (WN).

17. The image sensing device according to claim 12, further comprising:
a second pad metal layer having a top surface in contact with a bottom surface of the first pad metal layer and a bottom surface coupled to a through silicon via (TSV) penetrating a semiconductor substrate.

18. The image sensing device according to claim 17, wherein:
the second pad metal layer is integrated with the through silicon via (TSV).
